(19) United States
(12) Patent Application Publication
(10) Pub. No.: US 2023/0364968 A1
(43) Pub. Date: Nov. 16, 2023

(54) COMPUTE CLUSTER FOR AUTOMOTIVE COOLING FAN CONTROL

(71) Applicant: Ford Global Technologies, LLC, Dearborn, MI (US)

(72) Inventors: Michael Dupuis, Macomb, MI (US); Brock Watters, Livonia, MI (US)

(21) Appl. No.: 17/742,917

(22) Filed: May 12, 2022

(51) Int. Cl. B60H 1/00; H05K 7/20

(52) U.S. Cl. CPC B60H 1/00828; B60H 1/00807; B60H 1/00428; H05K 7/20209

(57) ABSTRACT

An automotive vehicle includes a housing, a plurality of fans arranged relative to the housing, a processor contained by the housing that generates control signals for the fans, and control circuitry including sensors that detect parameters associated with the housing and fans, and logic gates that, based on signals from the sensors, selectively generate output that interrupts the control signals and drives the fans.

### TECHNICAL FIELD

This disclosure relates to automotive cooling systems.

### BACKGROUND

An automotive climate control system may include subsystems and components, such as active heating and cooling elements, that cooperate to maintain cabin and other temperatures. This system is able to manage vehicle internal temperatures through a cycle of processes the either heat or cool air being circulated.

### SUMMARY

An automotive climate system includes at least one fan and control circuitry. The control circuitry includes at least one speed sensor that detects a speed of the at least one fan, at least one temperature sensor that detects a temperature, and logic gates that, responsive to signals indicative of the speed being less than a threshold speed and the temperature being greater than a threshold temperature, generate output to drive the at least one fan at a speed greater than the threshold speed.

Automotive control circuitry includes a plurality of temperature sensors that generate signals indicative of temperatures, a plurality of first comparators that generate logical output signals based on whether the signals indicative of the temperatures exceed a first threshold value, and an OR gate that generates a logical output signal based on a high or low state of the logical output signals generated by the first comparators. The automotive control circuitry also includes a plurality of speed sensors that generate signals indicative of speeds of fans, a plurality of second comparators that generate logical output signals based on whether the signals indicative of the speeds exceed a second threshold value, and an AND gate that generates a logical output signal based on a high or low state of the logical output signals generated by the second comparators and a high or low state of the logical output signal generated by the OR gate such that the logical output signal generated by the AND gate selectively drives the fans.

An automotive vehicle includes a housing, a plurality of fans arranged relative to the housing, a processor contained by the housing and that generates control signals for the fans, and control circuitry including sensors that detect parameters associated with the housing and fans, and logic gates that, based on signals from the sensors, selectively generate output that interrupts the control signals and drives the fans.

### BRIEF DESCRIPTION OF THE DRAWINGS

FIG. 1 is a schematic diagram of fan control circuitry.

FIG. 2 is a flow chart of an algorithm for fan control.

FIG. 3 is a schematic diagram of a vehicle including the control circuitry of FIG. 1.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Increasingly powerful processors are being packaged into more dense mechanical enclosures within vehicles. The heat generated by these processors as packaged may now require active cooling systems with fans to control the thermal environment. Managing the thermal environment may affect system reliability and stability.

If the cooling systems are unavailable, processors and other components may operate at high temperatures. Without active thermal management, the heat may build up inside any associated mechanical enclosure. Processors and components operating outside normal temperature ranges may cause radio frequency interference, resets of processors, errors in storage systems, and other issues affecting system integrity. Additionally, processors and storage exposed to high temperatures may experience shortened lifetimes.

Some vehicle consumers may expect a quiet vehicle cabin. Cooling fans operating at a high rate of speed may generate noise and because of this, speeds of the fans are controlled. The fans operate at the minimum speed required to manage the thermal environment and reduce the generated noise. Issues associated with the software, control circuit, or connection to the fans may prevent the fans from operating as desired.

Because of the effect high temperatures may have on system integrity, certain systems may include redundant cooling fans. Redundant fans allow the system to manage the thermal environment even with one of the fans being unavailable. This management is provided through a software function. Issues with associated processors or software could prevent proper thermal management of the system.

Vehicle features that operate while the vehicle is off and the driver is not in the vehicle, e.g., camera monitoring of the exterior of the vehicle, are increasing. Reducing the energy consumption of these features can prevent drain on the auxiliary battery (e.g., 12V battery) or reduction of the vehicle range to the extent battery power is used for propulsion. Therefore, processors and/or processor capabilities may not be active while a feature is on but the vehicle is off. This could include the thermal management system. If the system is operated longer than expected in this state, components could be exposed to high temperatures, which may affect system stability and create other issues.

Here, cooling fan control circuitry is contemplated. The circuit, in some examples, monitors multiple temperature sensors and the speed of the redundant cooling fans in parallel with the software function that controls fan speed. The circuit may turn the fan or fans on at full speed if any monitored temperature is above a defined threshold and the speed of all fans is below a defined threshold without any command from software. The circuit may be powered whenever the system has power and does not use the dedicated processor power supply, allowing it to be active independent of the associated processor. Powering the circuit from an independent power supply provides the ability to manage high temperatures even when one or more processors are not active or fully functional.

The temperature monitoring portion of the circuit may use analog temperature sensors whose voltage increases with increasing temperature. The output of these temperature sensors is compared to a calibrated reference voltage using a standard comparator. If the temperature output of any sensors is above the reference voltage, indicating a high temperature, the output of the comparator goes high. The outputs of all the temperature sensor comparators may be OR'd using transistor logic.

The fan speed of all cooling fans may be converted to a voltage using a frequency to voltage circuit whose output increases with increasing frequency. The output of this frequency to voltage converter is compared to a calibrated reference voltage using a standard comparator. If the frequency is too low and therefore the voltage is below the reference voltage, indicating the fan is not spinning, the output of the comparator goes high. The output of all the fan speeds may be AND'd using transistor logic.

The fan speed and temperature sensor monitoring outputs of the circuit may be AND'd together using standard transistor logic. If the fan speeds are too low and the enclosure temperature is above a limit, the circuit may interrupt the processor control signal using a standard buffer and pull the fan control signal high, commanding the fans to full speed.

The outputs of the fan speed and temperature comparators can be connected to a processor in the enclosure. This provides feedback to the software that an issue exists in the cooling system and/or issues in the hardware or software exist.

An advantage of the control circuit may be that it can be implemented with common, readily available and reasonably expensed components. That is, the circuit may be implemented with ordinary operational amplifiers, comparators, transistors, capacitors, and resistors. The control circuit may permit the fan to be turned on even if the processor controlling the fan is not powered. If any processor is active within the controller and fan control is not active, it is possible to heat the system. The control circuit may enable the fan in this situation based on temperature without processor control. The processor commanded fan speed can be over-ridden in the event of a software or processor issue. The circuit may independently monitor the temperature of the enclosure and if it exceeds a limit, the circuit may command the fan to maximum speed independent of the processor commanded fan speed. The control circuit can be expanded to support multiple cooling fans using readily available components.

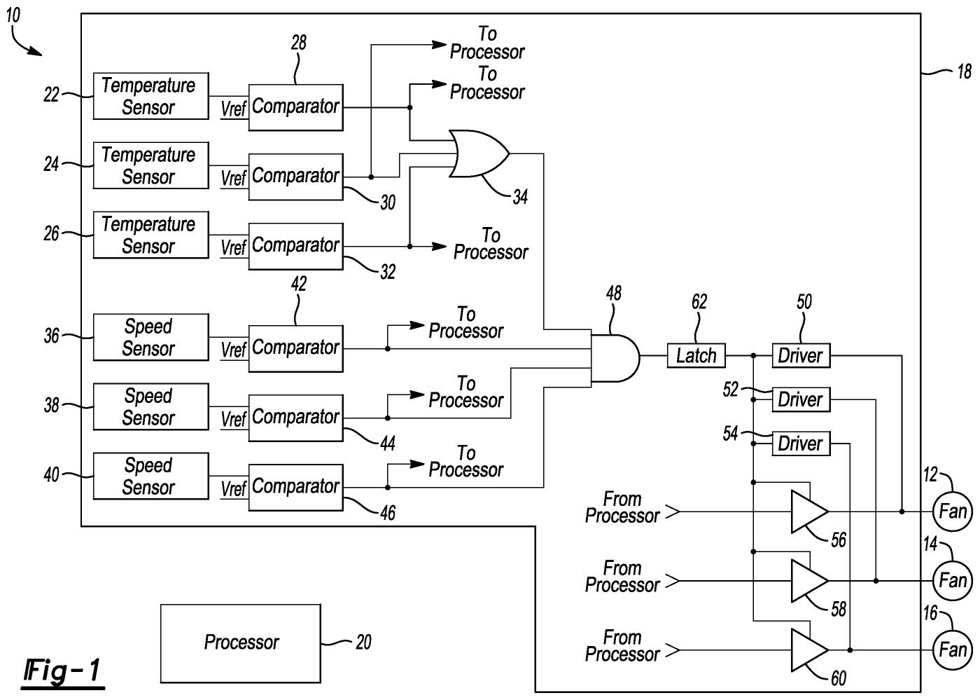

Referring to FIG. 1, an automotive climate system 10 may include a plurality of fans 12, 14, 16, control circuitry 18, and a processor 20. The control circuitry 18 includes temperature sensors 22, 24, 26, comparators 28, 30, 32, and OR gate 34. The temperature sensors 22, 24, 26 each detect a temperature corresponding with an automotive component, e.g., processing circuitry contained within an enclosure, etc. In this example, the sensed temperature is converted to a voltage signal such that as the temperature increases, the voltage increases. These signals are provided to the comparators 28, 30, 32. That is, output of the temperature sensor 22 is provided to the comparator 28, output of the temperature sensor 24 is provided to the comparator 30, and output of the temperature sensor 26 is provided to the comparator 32. Each of the comparators 28, 30, 32 is also provided a reference voltage value. This value may be predefined (identified via simulation or testing) and correspond to a threshold temperature. The comparators 28, 30, 32 are each configured such that responsive to a value of the voltage signal from the corresponding temperature sensor exceeding the reference voltage value, the comparator may output a high signal (e.g., 1). And responsive to the value of the voltage signal from the corresponding temperature sensor being less than the reference voltage value, the comparator may output a low signal (e.g., 0). The output from each of the comparators 28, 30, 32 is provided to the processor 20 and the OR gate 34. The processor 20 receives such data to inform it about the temperatures associated with the automotive component. It may then, for example, generate user alerts, etc. If all of the comparators 28, 30, 32 output a low signal (e.g., 0), the OR gate 34 will output a low signal (e.g., 0). If any of the comparators 28, 30, 32 outputs a high signal (e.g., 1), the OR gate 34 will output a high signal (e.g., 1).

The control circuitry 18 also includes speed sensors 36, 38, 40, comparators 42, 44, 46, and AND gate 48. The speed sensors 36, 38, 40 each detect a frequency corresponding to operation of the fans 12, 14, 16. That is, the speed sensor 36 detects a frequency corresponding to operation of the fan 12, the speed sensor 38 detects a frequency corresponding to operation of the fan 14, and the speed sensor 40 detects a frequency corresponding to operation of the fan 16. In this example, the sensed frequency is converted to a voltage signal such that as the frequency increases, the voltage increases. These signals are provided to the comparators 42, 44, 46. That is, output from the speed sensor 36 is provided to the comparator 42, output from the speed sensor 38 is provided to the comparator 44, and output from the speed sensor 40 is provided to the comparator 46. Each of the comparators 42, 44, 46 is also provided a reference voltage value. This value may be predefined (identified via simulation or testing) and correspond to a threshold speed. The comparators 42, 44, 46 are each configured such that responsive to a value of the voltage signal from the corresponding speed sensor exceeding the reference voltage value, the comparator may output a low signal (e.g., 0). And responsive to the value of the voltage signal from the corresponding speed sensor being less than the reference voltage value, the comparator may output a high signal (e.g., 1). The output from each of the comparators 42, 44, 46 is provided to the processor 20 and the AND gate 48. The processor 20 receives such data to inform it about the speeds associated with the fans 12, 14, 16. It may then, for example, generate user alerts, etc. The output from the OR gate 34 is also provided to the AND gate 34. If any of the comparators 42, 44, 46 outputs a high signal (e.g., 1) and the OR gate 34 outputs a high signal (e.g., 1), the AND gate 48 will output a high signal (e.g., 1). Otherwise, the AND gate 48 will output a low signal (e.g., 0).

The control circuitry also includes drivers 50, 52, 54, buffers 56, 58, 60, and latch 62. The drivers 50, 52, 54 are configured to provide voltage signals to the fans 12, 14, 16 that cause the fans 12,14, 16 to operate at high speed (e.g., higher than the threshold speed) responsive to output of a high signal (e.g., 1) from the AND gate 48. That is, the driver 50 is configured to provide a voltage signal to the fan 12, the driver 52 is configured to provide a voltage signal to the fan 14, and the driver 54 is configured to provide a voltage signal to the fan 16. Otherwise, the drivers 50, 52, 54 do not provide voltage signals to the fans 12, 14, 16. The buffers 56, 58, 60 are configured to interrupt the normal control signals from the processor 20 that control the fans 12, 14, 16 responsive to output of a high signal (e.g., 1) from the AND gate 48. This interrupt functionality permits the voltage signals from the drivers 50, 52, 54 to supplant those from the processor 20. If the processor 20 is not operating properly, the fans 12, 14, 16 can nonetheless receive commands to operate as described above.

The latch 62 is configured to hold a high signal (e.g., 1) from the AND gate 48 until, for example, the climate system 10 is powered down (e.g., key off). Without the latch 62, the AND gate 48 would output a low signal (e.g., 0) as soon as the speeds of the fans 12, 14, 16 exceed the threshold speed: The comparators 42, 44, 46 would output a low signal (e.g., 0) responsive to the fan speeds measured by the speed sensors 36, 38, 40 exceeding the threshold, resulting in the AND gate 48 outputting a low signal (e.g., 0).

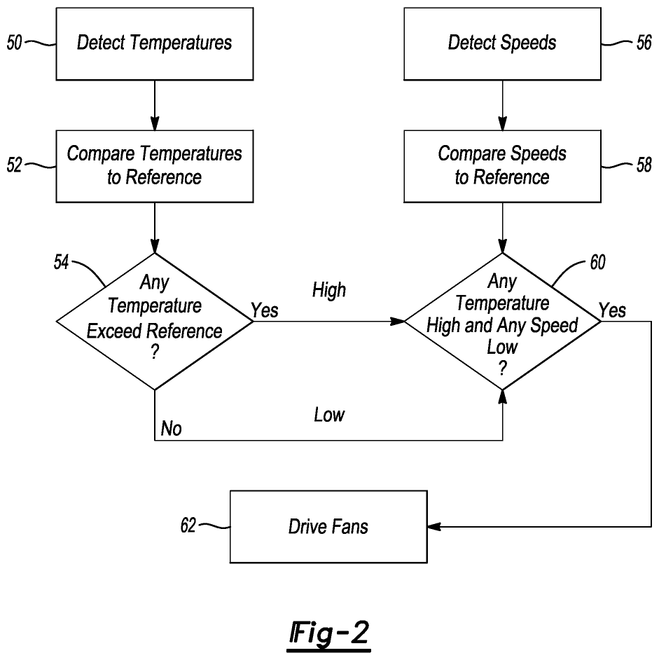

Referring to FIG. 2, some of the control operations are described as a flow diagram. At operation 50, temperatures are detected. At operation 52, the temperatures are compared to a reference. If any of the temperatures is greater than a predefined threshold, a high signal is output at operation 54. Otherwise, a low signal is output. At operation 56, speeds are detected. At operation 58, the speeds are compared to a reference. If any of the speeds are low and a temperature is high, a high signal is output at operation 60, which drives fans at operation 62. Otherwise, a low signal is output.

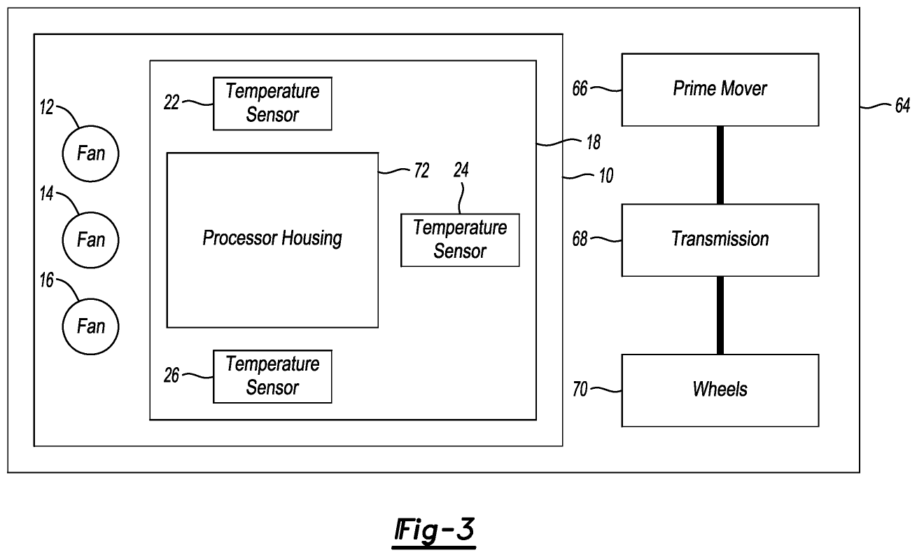

Referring to FIG. 3, an automotive vehicle 64 may include the climate system 10, a prime mover 66 (e.g., an electric machine, an internal combustion engine, etc.), a transmission 68, and wheels 70. The prime mover 66 may generate mechanical power 66 that is transferred to the wheels 70 via the transmission 68 as known in the art. Portions of the control circuitry 18 are illustrated, including a processor housing 72 that may house the processor 20, or other processors. The fans 12, 14, 16 are arranged to direct air over the processor housing 72, and the temperature sensors 22, 24, 26 are arranged around the processor housing 72 to detect temperatures therearound. Other arrangements and configurations, however, are also contemplated.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. In the example of FIG. 1, three fans, three temperature sensors, three speed sensors, etc. are shown. The proposed circuitry, however, may be configured for any number of fans, sensors, etc. Moreover, the number of temperature sensors need not match the number of fans. A single temperature sensor, for example, could be used in a system with four fans, etc. In other examples, different logic gate arrangements may be used to implement the operations described above.

The words used in the specification are words of description rather than limitation, and it is understood that various changes may be made without departing from the spirit and scope of the disclosure. The words controller and controllers as well as processor and processors may be interchanged herein.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An automotive climate system comprising:
at least one fan; and
control circuitry including at least one speed sensor configured to detect a speed of the at least one fan, at least one temperature sensor configured to detect a temperature, and logic gates configured to, responsive to signals indicative of the speed being less than a threshold speed and the temperature being greater than a threshold temperature, generate output to drive the at least one fan at a speed greater than the threshold speed.

2. The automotive climate system of claim 1, wherein the control circuitry further includes a latch configured to hold the output to drive the at least one fan at the speed greater than the threshold speed regardless of the signals until climate system power down.

3. The automotive climate system of claim 1, wherein the control circuitry further includes at least one driver configured to convert the output to a voltage signal to drive the at least one fan.

4. The automotive climate system of claim 1, wherein the logic gates include an OR gate configured to receive signals associated with the at least one temperature sensor and an AND gate configured to receive a signal from the OR gate and signals associated with the at least one speed sensor.

5. The automotive climate system of claim 1 further comprising at least one processor configured to generate control signals for the at least one fan.

6. The automotive climate system of claim 5, wherein the control circuitry further includes at least one buffer configured to interrupt the control signals responsive to the output.

7. The automotive climate system of claim 5, wherein the at least one fan is arranged to cool the processor.

8. The automotive climate system of claim 1, wherein a number of the at least one speed sensor is equal to a number of the at least one fan.

9. The automotive climate system of claim 1, wherein a number of the at least one temperature sensor is equal to a number of the at least one fan.

10. Automotive control circuitry comprising:
a plurality of temperature sensors configured to generate signals indicative of temperatures;
a plurality of first comparators configured to generate logical output signals based on whether the signals indicative of the temperatures exceed a first threshold value;
an OR gate configured to generate a logical output signal based on a high or low state of the logical output signals generated by the first comparators;
a plurality of speed sensors configured to generate signals indicative of speeds of fans;
a plurality of second comparators configured to generate logical output signals based on whether the signals indicative of the speeds exceed a second threshold value; and
an AND gate configured to generate a logical output signal based on a high or low state of the logical output signals generated by the second comparators and a high or low state of the logical output signal generated by the OR gate such that the logical output signal generated by the AND gate selectively drives the fans.

11. The automotive control circuitry of claim 10 further comprising a latch configured to hold a state of the logical output signal generated by the AND gate until control circuitry power down.

12. The automotive control circuitry of claim 10 further comprising a plurality of drivers configured to convert the logical output signal generated by the AND gate to voltage signals to drive the fans.

13. The automotive control circuitry of claim 10 further comprising a plurality of buffers configured to interrupt control signals output by a processor for the fans responsive to the logical output signal generated by the AND gate.

14. The automotive control circuitry of claim 10, wherein a number of the speed sensors is equal to a number of the fans.

15. The automotive control circuitry of claim 10, wherein a number of the temperature sensors is equal to a number of the fans.

16. An automotive vehicle comprising:
a housing;
a plurality of fans arranged relative to the housing;
a processor contained by the housing and configured to generate control signals for the fans; and
control circuitry including sensors configured to detect parameters associated with the housing and fans, and logic gates configured to, based on signals from the sensors, selectively generate output that interrupts the control signals and drives the fans.

17. The automotive vehicle of claim 16, wherein the control circuitry further includes a plurality of drivers configured to convert the output to voltage signals to drive the fans.

18. The automotive vehicle of claim 16, wherein the control circuitry further includes a latch configured to hold the output until vehicle power down.

19. The automotive vehicle of claim 16, wherein the logic gates include an OR gate configured to receive signals from some of the sensors and an AND gate configured to receive signals from other of the sensors and the OR gate.

20. The automotive vehicle of claim 16, wherein the sensors include temperature sensors and speed sensors.
